(19) United States
(12) Patent Application Publication
(10) Pub. No.: US 2008/0037213 A1
(43) Pub. Date: Feb. 14, 2008

(54) Computer stand with cooling mechanism

(76) Inventor: Edgar Diego Haren, Houston, TX (US)

Correspondence Address: STOEL RIVES LLP - SLC, 201 SOUTH MAIN STREET, ONE UTAH CENTER, SALT LAKE CITY, UT, 84111, US

(21) Appl. No.: 11/501,485

(22) Filed: Aug. 8, 2006

(51) Int. Cl. A47F 5/12; G06F 1/20; H05K 7/20; H05K 5/00

(52) U.S. Cl. 361/687; 108/7

(57) ABSTRACT

Provided herein is a computer stand that can include a platform, a support mechanism, and a cooling mechanism. The platform can have a substantially planar portion and can be configured to support a computing device. A support mechanism can be included and configured to elevate at least one end of the platform above a work surface. The cooling mechanism can be configured to facilitate heat dissipation from a computing device.

### FIELD OF THE INVENTION

The present invention relates generally to computer systems and more particularly to a novel and unique computer stand.

### BACKGROUND OF THE INVENTION

Computing devices of various configurations and capabilities have become commonplace in today's home and business environment. Increases in processing capability and smaller, low power consumption configurations has led to a proliferation of portable computing devices. Laptops, notebooks, PDAs, palmtops and other computing devices are finding widespread utilization for business, entertainment, personal and other uses.

Computer stands have increased in popularity along with the computing device. Computer stands can be used, with or without port replication facilities, to provide a stable work platform for the computing device. Monitor stands, for example, can be used to place computer monitors at a comfortable height above the work surface. Docking stations allow the insertion and removal of portable computers for quick hook-up to the working environment.

### BRIEF SUMMARY OF THE INVENTION

The present invention is directed towards a computer stand. In some embodiments, the computer stand comprises: a platform having a substantially planar portion that comprises a first surface, the planar portion defining a first and second axis, wherein the platform is further configured to support a computing device; a support mechanism attached to the platform, wherein the support mechanism is configured to elevate at least one end of the platform above a work surface; and a cooling mechanism disposed on the platform, wherein the cooling mechanism is configured to facilitate heat dissipation from a computing device.

The cooling mechanism may comprise a passive or active cooling mechanism. The passive cooling mechanism may comprise at least one of perforations, slots, porous materials, meshed materials, other permeable materials, and other openings. The active cooling mechanism may be an integral part of the platform and may comprise a cooling fan or Peltier device. Alternatively, the active cooling mechanism may be a modular component that is removably mounted in or on the platform and may also comprise a cooling fan or Peltier device. A modular active cooling component may be removably mounted in an opening configured to passively cool a computing device when the modular component is not mounted in the opening. The opening may comprise a support member at least partially extending around the opening to hold the modular component and a catch mechanism to secure the modular component when mounted in the opening. In some embodiments, the modular component may be used as a stand-alone device to cool a computing device when the modular component is not mounted in the platform of the computer stand.

The support mechanism may comprise of an interface mechanism. In other embodiments, the platform may comprise of an interface mechanism. In embodiments wherein the active cooling mechanism is a modular component that is removably mounted in or on the platform, the modular component may comprise of an interface mechanism.

The computer stand may further comprise of a locking mechanism. The locking mechanism may be integrated with the platform and configured to lock the computing device in place on the platform.

In other embodiments, the platform may be further comprised of embossments, reliefs, or other designs and patterns.

The support mechanism may be further configured to be releasable or adjustable in order to elevate the platform at various heights and angles above the work surface.

In some embodiments, the computer stand comprises: a platform having a substantially planar portion that comprises a first surface, the planar portion defining a first and second axis; a support mechanism attached to the platform; and a cooling mechanism disposed on the platform.

In some embodiments, the computer stand comprises: a means for supporting a computing device; a means for elevating above a work surface at least one end of the means for supporting a computing device; and a means for cooling a computing device by facilitating heat dissipation.

Further features and advantages of the present invention, as well as the structure and operation of various embodiments of the present invention, are described in detail below with reference to the accompanying drawings.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

FIG. 1 is a diagram illustrating one example implementation of computer stand accordance with one embodiment of the invention.

FIG. 2 is a diagram illustrating an exemplary configuration for a handle in accordance with one embodiment of the invention.

FIG. 3 is a diagram illustrating a computer stand incorporating a removably mounted dular active cooling device with one embodiment of the invention.

FIGS. 4A, 4B and 4C illustrate a few example configurations of a retaining structure in accordance with various embodiments of the invention.

FIG. 5 is a diagram illustrating one example configuration of a locking mechanism in accordance with one embodiment of the invention.

FIG. 6 is a diagram illustrating another embodiment for securing a computing device to the computer stand in accordance with one embodiment of the invention.

FIG. 7 is a diagram illustrating a rear perspective view of a computer stand that includes a port replicator in accordance with one embodiment of the invention.

FIG. 8 is a diagram illustrating an exemplary configuration of an adjustable support structure in accordance with one embodiment of the invention.

FIG. 9 is a diagram illustrating yet another example configuration for a support structure in accordance with one embodiment of the invention.

FIG. 10 is a diagram illustrating an example active cooling device in accordance with one embodiment of the invention.

FIG. 11 is a diagram illustrating an example implementation for an active cooling device implemented as a computer stand in accordance with one embodiment of the invention.

FIG. 12 is a cutaway figure illustrating one possible embodiment of a locking mechanism.

### DESCRIPTION OF THE PREFERRED EMBODIMENTS

The present invention is directed toward various approaches to supporting a portable computing device. As used herein, the term computing device can refer to any of a number of configurations of portable electronic devices including laptop computers, notebook computers, personal digital assistants, MP3 and DVD players and other electronic devices of varying configurations and application. For ease of description, the invention is described herein from time to time in terms of a notebook computer. However, after reading this description it will become apparent to one of ordinary skill in the art how the invention can be used with other electronic devices.

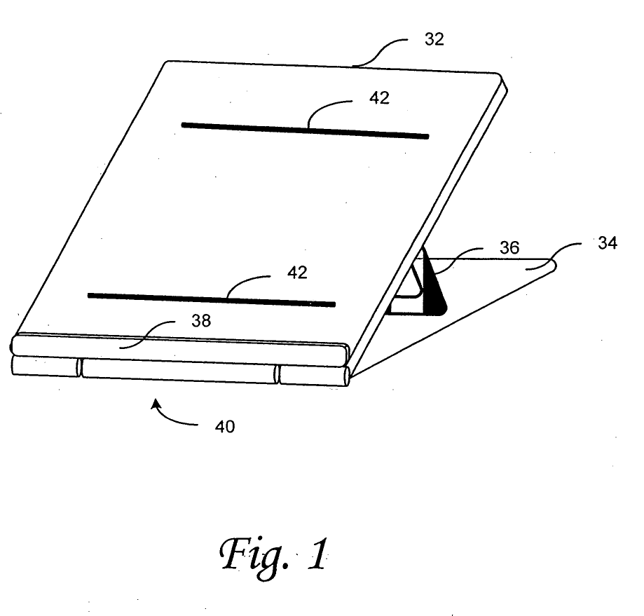

One embodiment of the invention includes a stand that can be used to support a notebook computer or other electronic device. FIG. 1 is a diagram illustrating one example implementation of such a support in accordance with one embodiment of the invention. Referring now to FIG. 1, the example stand can include a platform 32, a base structure 34, a support structure 36, a hinge mechanism 40 and a retaining unit 38.

Platform 32 can generally be configured so as to provide a supporting surface for the bottom of a computing device (not illustrated). For example, in one embodiment, platform 32 is a relatively planar surface that provides a suitable base on which to rest a laptop computer, notebook computer, portable computer or other computing device. Platform 32 can be made of a polycarbonate material in a variety of colors or finishes or of any other material suitable for such purposes. In one embodiment, platform 32 is made of a relatively lightweight material to enhance portability.

Platform 32 can be relatively smooth or it can include embossments, relief or other designs or patterns thereon. In one embodiment, platform 32 includes rubber or rubber-like structures or other material with a relatively high coefficient of friction to provide a relatively non-slip surface to help maintain the laptop computer or other computing device in position on the platform. In some embodiments, the platform may also include an opening, compartment or other fitment for mounting a removable modular component for actively cooling a computing device. Such an opening can include a support member to hold the modular component. For example, a support member can be included to extend at least partially around the opening to hold the modular cooling component. Additionally, a catch mechanism can be included to secure the modular component when mounted in the opening. In one embodiment, the catch mechanism is releasably engageable to allow the modular component to be installed and removed with relative ease. The support member may be configured in many ways to support the modular component. For example, the support member might comprise a lip of material around the edges of the opening, brackets spanning the length or width of the opening, and other configurations. The catch mechanism may also be configured in many ways, and may comprise a latch, a spring or resilient catch mechanism, retractable bars, retractable pins, or other securing mechanisms.

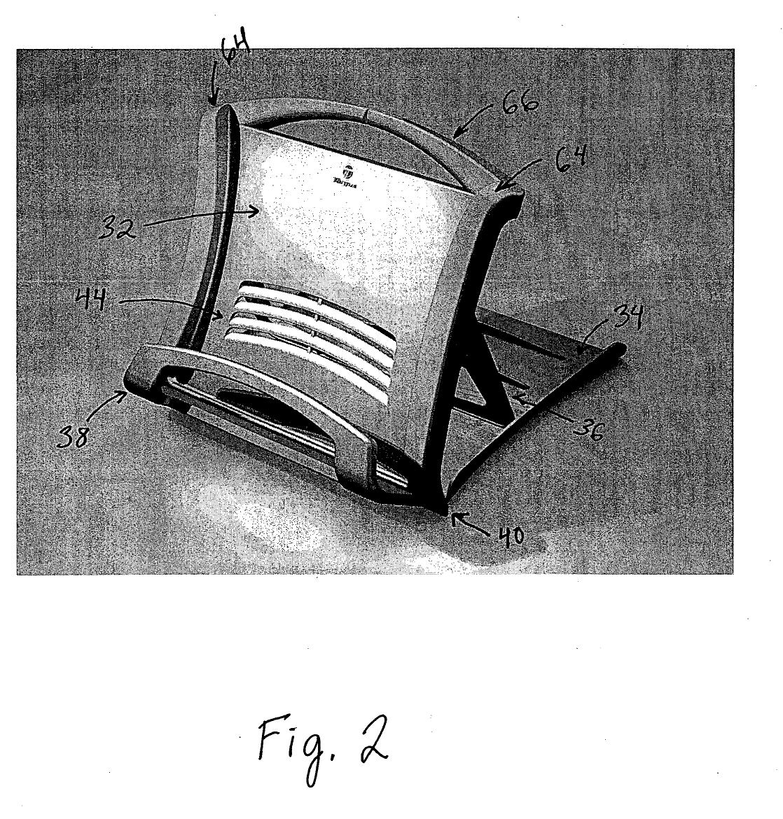

Platform 32 can also include passive cooling elements such as perforations, slots or other openings 44 (see, e.g., FIG. 2) to allow cooling of the electronic device positioned thereon. Additionally, porous, meshed or other permeable materials can be used in some or all of platform 32 to allow airflow or otherwise improve heat dissipation from the electronic device.

In addition to or in place of non-skid surfaces 42, retaining unit 38 can be included and disposed near the lower end of platform 32 to support the computing device when platform 32 is in a raised position. Any of a number of various configurations can be provided for retaining unit 38 including, a simple flat panel, a raised member, a stud, ridge, or other various embodiments as described in further detail below.

A support mechanism or structure 36 can be included to elevate platform 32 above the desktop, tabletop, bench, or other work surface area (generally referred to as a work surface). In the example illustrated in FIG. 1, support structure 36 is configured to attach at a point to the rear of the center line of platform 32 such that platform 32 can be elevated at the distal end while the proximal end of platform 32 remains in relatively close proximity with the work surface or base structure 34. Other configurations of the support structure 36 can be provided so as to elevate platform 32 approximately horizontally as opposed to in an angular fashion as illustrated in FIG. 1.

In some embodiments, the support mechanism 36 is releasable or adjustable so that the platform may be elevated at various heights and angles above a work surface or base structure. Support mechanism or structure 36 in its various embodiments can advantageously provide the feature of elevating the monitor or display screen of the computing device to a higher level for more comfortable viewing by the user. Thus, in operation, the notebook computer can be placed on platform 32 and the laptop opened with the monitor in a substantially upright position. Raising platform 32 (either entirely, or just at the distal end) can serve to raise the height of the notebook computer monitor to a more comfortable position for viewing. For example, one embodiment can allow the user to angle the notebook computer enough for cooling and for viewing yet allow the keyboard to remain in a position such that it is operable without ergonomic restraints.

A pivot mechanism 40 can also be provided to allow platform 32 to be displaced in pivotal relation to base structure 34. Pivot mechanism 40 can be any of a number of pivot, hinged or other mechanisms that permit rotation about an axis or other like motion. In embodiments including a pivot mechanism 40, the stand can be folded (in some embodiments substantially flat) such that it consumes less space for storage or transportation. In use, the stand can be opened and raised to a desired height. Height can be maintained by support mechanism or structure 36 as described above. In embodiments where a pivot mechanism 40 or other like mechanism is provided, as well as in other embodiments, support structure 36 can also be pivotally mounted such that it can be rotated into position to support platform 32 or folded for storage. As such, support structure 36 can either pivot at an axis close to platform 32 or close to base structure 34.

Base structure 34 can be included to provide a relatively stable surface to allow the stand to rest with relative security on the work surface. Thus, in one embodiment, base structure 34 includes a relatively flat undersurface to provide a stable resting platform with the corresponding work surface. As discussed in some further embodiments below, the base structure can take on a number of different shapes and configurations and can further include storage areas or compartments for peripherals and other components as well as provide space for an interface mechanism, including a port replicator or other like device. In addition to a port replicator, a power module can be included to provide additional outlets of power for the computing device or for other devices.

Where a base structure 34 is not provided, a support structure 36 or other like mechanism can still be included to elevate platform 32 angularly or horizontally above the work surface.

In one embodiment, a handle or like structure can be included with or incorporated into the stand to facilitate transportation of the device. FIG. 2 is a diagram illustrating an exemplary configuration for such a handle in accordance with one embodiment of the invention. Referring now to FIG. 2, in this example embodiment, a pair of side members 64 extend from platform 32. A cross member 66 connects the two side members 64 forming a gap between cross member 66 and platform 32. As such, a handle can be formed at the end of platform 32 to allow the stand to be carried with relative ease. Members 64, 66 can be molded or formed of the same material as platform 32 and, in one embodiment, members 64, 66 and platform 32 are molded in one piece.

In various embodiments described below, locking or other retention mechanisms can be provided with the stand to fixedly secure the portable computer or other computing device to the stand. In these embodiments, the stand can be carried with the computing device secured thereto for relative ease of transport.

Although the example embodiment depicted in FIG. 2 illustrates a relatively arcuate shaped handle, other shapes, sizes and configurations can be implemented to provide a gripping mechanism. For example, a more rectangular shaped member can extend across the upper edge of platform 32 leaving a gap between the rectangular member and the platform to provide a place for a handhold. Additionally, a recess or other like structure can be included to allow the device to be gripped appropriately by a user. While the embodiment illustrated in FIG. 2 depicts a handle mechanism that is integrated as a part of platform 32, other embodiments are contemplated wherein the handle is not an integral portion of platform 32. For example, in some embodiments, a handle or handle-like mechanism can be slideably, detachably or pivotally mounted to platform 32 such that it can slide or fold out of the way or simply be removed when not in use. A handle or handle-like mechanism can also be slideably, detachably or pivotally mounted to base structure 34.

As stated above with reference to FIG. 1, and as seen in FIG. 2, platform 32 can include various configurations of slots (or openings of other configurations), channels, perforations, or other passive cooling mechanisms 44 to allow airflow across the base of the portable computing device to help with heat dissipation.

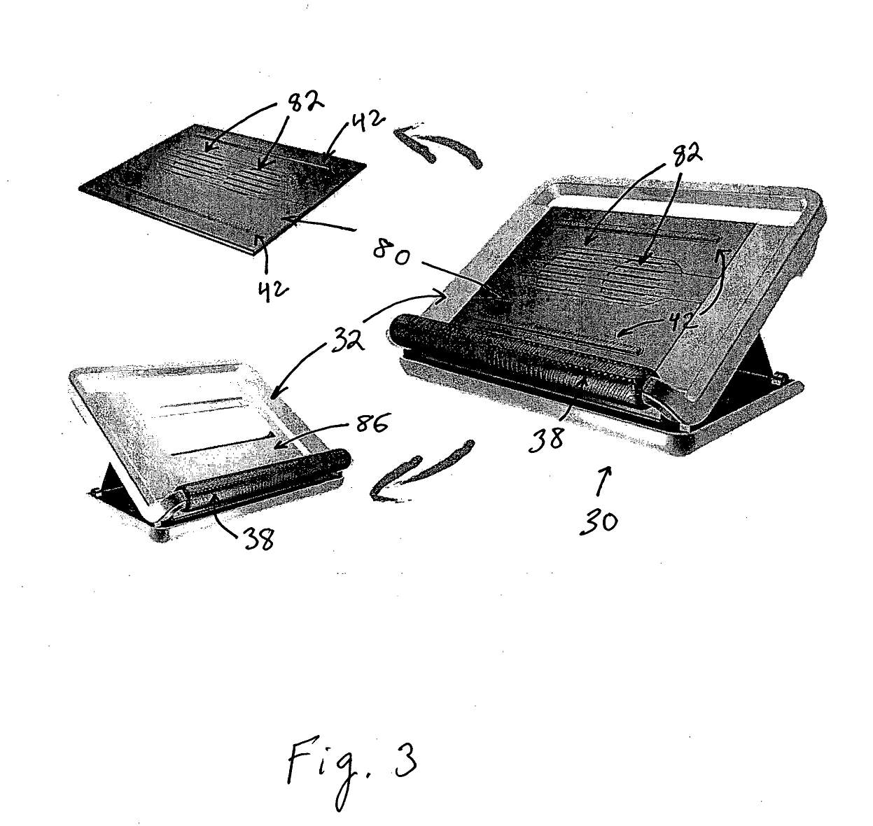

In another embodiment, active cooling mechanisms 80 can be incorporated into platform 32 to facilitate heat dissipation from the computing device. Such active cooling mechanisms 80 may be fully integrated into (i.e., not removable from) platform 32, or may consist of removably mounted modular components. FIG. 3 is a diagram illustrating a computer stand that includes a removably mounted modular active cooling device 80 in one embodiment of the invention. Referring now to FIG. 3, removably mounted in platform 32 is a modular active cooling device 80 that uses two cooling fans 82, which can be used to provide airflow across the bottom of the computing device. The cooling fans 82 may be covered with grates to protect the user from the turning fans or to otherwise limit the likelihood of foreign objects contacting the rotating fan vanes, as illustrated in FIG. 3. Although two cooling fans 82 are illustrated, any number of cooling fans can be utilized depending on the capacity of the fans and the cooling needs. In addition to cooling fans, other active cooling devices such as, for example, Peltier devices, can be used to assist with the cooling of the computing device.

The surface of the modular active cooling device 80 may include rubber or rubber-like structures or other material with a relatively high coefficient of friction 42 to provide a relatively non-slip surface to help maintain the laptop computer or other computing device in position. In some embodiments, the surface of the modular active cooling device 80 may comprise embossments, reliefs, or other designs and patterns.

The opening 86 in the platform in which the active cooling device 80 is removably mounted may be perforated so that air may circulate freely even if the modular active cooling device 80 is not inserted into the opening (see FIG. 3). The opening may be configured in any of a number of convenient and useful ways in order to permit mounting of the modular active cooling device 80. The opening 86 may comprise a support member at least partially extending around the opening to hold the modular component and a catch mechanism to secure the modular component when mounted in the opening. The support member in some embodiments may comprise a lip of material strong enough to hold the modular cooling component. The catch mechanism in some embodiments may comprise a latch, retractable bars, retractable pins, or other mechanism that secures the modular active cooling device when mounted in the opening. Note that other components of the computer stand 30 may be removably mounted. For example, as illustrated in FIG. 3, one embodiment of the invention may utilize modular retaining units 38 that can be switched depending on the particular needs of the user.

In embodiments with removably mounted active cooling devices 80, the modular active cooling devices can be added as aftermarket or optional features with the computer stand 30 and can be removed or replaced depending on cooling requirements or the user's desires. Still further, in some embodiments, platform 32 can be configured in such a way so as to allow the placement of the active cooling devices to be made to maximize their effect with the particular computing device. For example, a plurality of channels spaced along platform 32 can be provided, wherein each of the channels can accommodate an active cooling device. As another example, a matrix of openings can be distributed across the platform 32. Thus, in such embodiments, a user can place an active cooling device in the channel or opening such that it is positioned in a location so as to make good use of its cooling effects.

As illustrated in FIG. 1 and FIG. 3, ridges, bumps, (as well as members 42) or other elevations can be provided on the surface of platform 32 or active cooling device 80 so as to raise the base of the computing device above platform 32 or active cooling device 80. This can improve the airflow on the undersurface of the computing device.

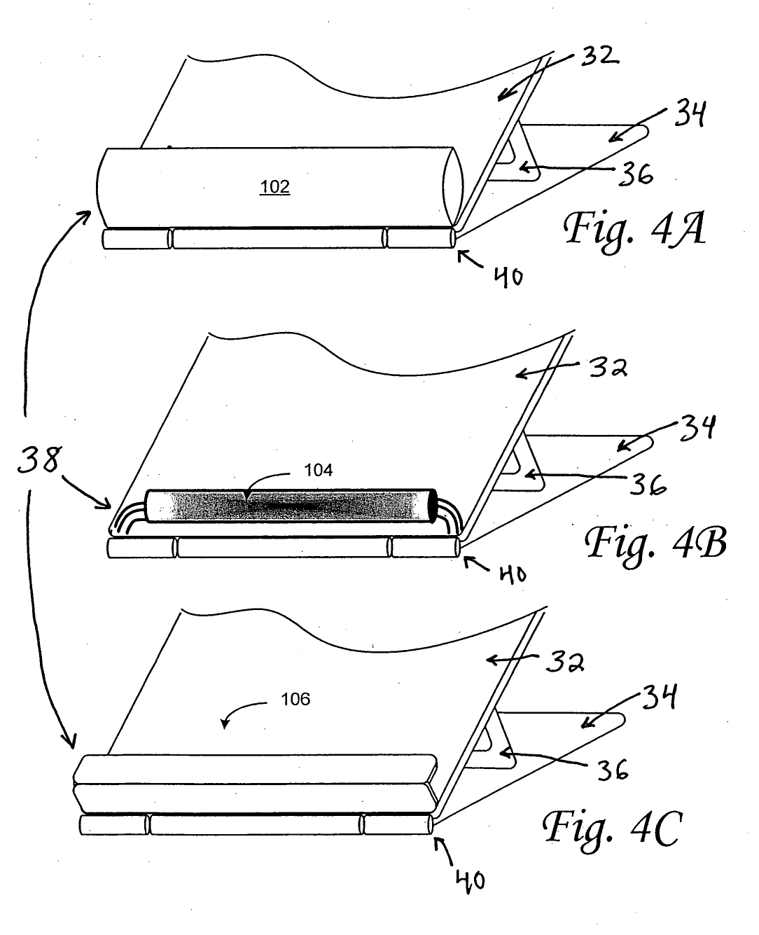

As stated above, various retaining structures 38 can be included to support the computing device as it rests on an elevated computer stand. FIGS. 4A, 4B and 4C illustrate a few example configurations of such a retaining structure 38 in accordance with various embodiments of the invention. These various retaining structures 38 may be configured so as to be fully integrated into (i.e., not removable from) platform 32. Alternatively, the retaining structures 38 may be configured as removably mounted modular retaining structures 38 that can be switched depending on the particular needs of the user.

Referring now to FIG. 4A, a channel-like structure 102 can be provided at the proximal end of platform 32 to support the computing device positioned thereon. In one embodiment, channel 102 is of a sufficient height and width to support the insertion of the computing device therein. Thus, the computing device can be held in place on platform 32 with a relative level of security. In the example illustrated in FIG. 4B, a padded member 104 can be provided at the base of platform 32 to provide a cushioned resting point for the computing device. In the embodiment illustrated in FIG. 4B, a U-shaped arm can be provided with padding disposed thereon to support the computing device. However, as this example illustrates, other configurations for a padded member 104 can be provided.

In yet another embodiment, illustrated in FIG. 4C, retaining member 38 can be an angle bracket 106 or other like simple structure. Although the angle bracket 106 illustrated in FIG. 4C spans almost the entire width of platform 32, angle bracket 106 can be of different widths and can even be segmented into multiple brackets if desired. As these above examples depicted in FIG. 4 illustrate, retaining member 38 can be implemented in any of a variety of structures, shapes or configurations to provide support for the computing device on platform 32. Additionally, retaining member 38 can be configured so as to extend across at least a portion of the top of the computing device (such as with angle bracket 106 or channel 102) to provide additional support and security for the computing device.

According to yet another embodiment of the invention, locking features can be provided to secure the computing device to the computer stand 30. In one embodiment, a locking mechanism can be included with platform 32 to provide a measure of security against theft of the computing device and to hold the computing device securely in place when it is being transported with the computer stand 30. Although a variety of locking mechanism configurations can be provided, one exemplary configuration is now described. FIG. 5 is a diagram illustrating one such example configuration in accordance with one embodiment of the invention. Referring now to FIG. 5, the illustrated embodiment includes blocking structures in combination with movable members to hold the computing device securely in place on platform 32. In the illustrated example, the blocking structures include a moveable angle bracket 134 mounted at or in proximity to a first edge of platform 32, and relatively flat fixed panels 136 mounted opposite angle bracket 134. The moveable angle bracket 134 can be translated toward the flat fixed panels 136, thereby helping to secure the computing device. Although FIG. 5 portrays angle bracket 134 as moveable and the flat panels 136 as fixed, it is readily apparent to one of ordinary skill in the art that other configurations can be implemented with movable or combinations of movable and fixed brackets of various shapes and dimensions.

Additionally, in the embodiment illustrated in FIG. 5, other movable members may comprise two movable members 138 slideably mounted to platform 32 such that they can be translated toward and away from each other to engage and disengage from the computing device. In an alternative embodiment not illustrated, the movable members can be pivotally mounted to platform 32 such that they can be pivoted into and out of a locking position, thereby engaging and disengaging the computing device.

In the embodiment illustrated in FIG. 5, movable members 138 comprise angle brackets configured to engage a portion of the computing device such that it cannot be lifted from platform 32. It will become apparent to one of ordinary skill in the art after reading this description how alternative shaped members can be provided in place of the angle brackets illustrated in FIG. 5.

Operation of movable members 138 as illustrated in FIG. 5 is now described. Movable members 138 in this embodiment can be placed in a first position (translated away from one another) to accept positioning of the computing device on platform 32. This position places movable members 138 far enough apart from one another such that the computing device can slip in between the inner edges of movable members 138 and be slid under angle bracket 134. With the computing device disposed in a relatively parallel orientation relative to platform 32, movable members 138 can be slideably moved toward one another to securely engage the computing device on platform 32.

Movable members 138, whether movable by sliding, pivoting or other movable mechanism, can be locked into place with various locking mechanisms to prevent them from being disengaged; thereby hindering efforts to remove the computing device from the computer stand 30. One example embodiment of a locking mechanism is depicted in cutaway FIG. 12. Referring now to FIG. 12 the proximal ends of the movable members 138 may be placed in contact with small cogwheels 140. As the opposed movable members 138 are translated towards each other, teeth on the proximal ends of the movable members 138 engage the teeth on the small cogwheels 140, causing the cogwheels to turn counterclockwise. The small cogwheels 140 turn clockwise when the movable members 138 are translated away from each other.

It will be readily apparent to one of ordinary skill in the art that a variety of approaches can be used to lock the movable members 138 into place, thereby securing the computing device into place. For example, a locking mechanism can be configured to lock the small cogwheels 140 into place, preventing rotation of the cogwheels 140 and thereby preventing translation of the movable members 138. Alternatively, a locking mechanism can be configured so as to directly engage the teeth on the proximal ends of the movable members 138, thereby directly preventing one movable member 138 from translating towards or away from the other movable member 138. In one embodiment, the user may turn a knob on the exterior of the platform 32 in order to adjust the position of the movable members 138. A locking mechanism could prevent an unauthorized user from turning the knob, preventing the movable members 138 from changing position and thereby securing a computing device in place. It would be apparent to one of ordinary skill in the art after reading this description that there are numerous different locking mechanisms that can be used to prevent movement of the locking members, thereby allowing them to secure the computing device into place on the stand. These mechanisms could be purely mechanical or may incorporate various electronic components.

In the embodiment depicted in FIG. 5, the blocking structures are illustrated as fixed members, including an angle bracket 134 at the proximal end of platform 32 and a flat panel 136 at the far end. This configuration allows the computing device to be slid into place on platform 32, then locked into place by engagement of movable members 138. In alternative embodiments, one or more blocking structures can be movably mounted so as to engage the computing device. As with the movable members, blocking structures can be mounted using sliding mechanisms (to allow translation in a direction parallel to or orthogonal to platform 32), pivot mechanisms, displacement mechanisms or other moving mechanism, enabling the blocking structures to move in an out of an engaged position. As with movable members, other shapes and configurations are contemplated, and they can be locked into place with a suitable locking mechanism. Also, in one embodiment, the various blocking and movable members can be positioned about platform 32 in locations other than those as illustrated in FIG. 5. In yet another embodiment, these members can be made thin enough to allow clamshell-configured computing devices to be closed or opened while the members are engaged. As in other embodiments, a fully integrated (non-removable) active cooling device 80 or a removably mounted modular active cooling device 80 may be incorporated into the platform 32.

In one embodiment, movable members 138 and the blocking members are shaped so as not to interfere with the keyboard or other user interface elements of the computing device mounted on platform 32. In one embodiment, however, movable members or the blocking members can extend farther across the computing device to provide additional security. Such embodiments may be acceptable in situations where, for example, an external keyboard is used with the computing device.

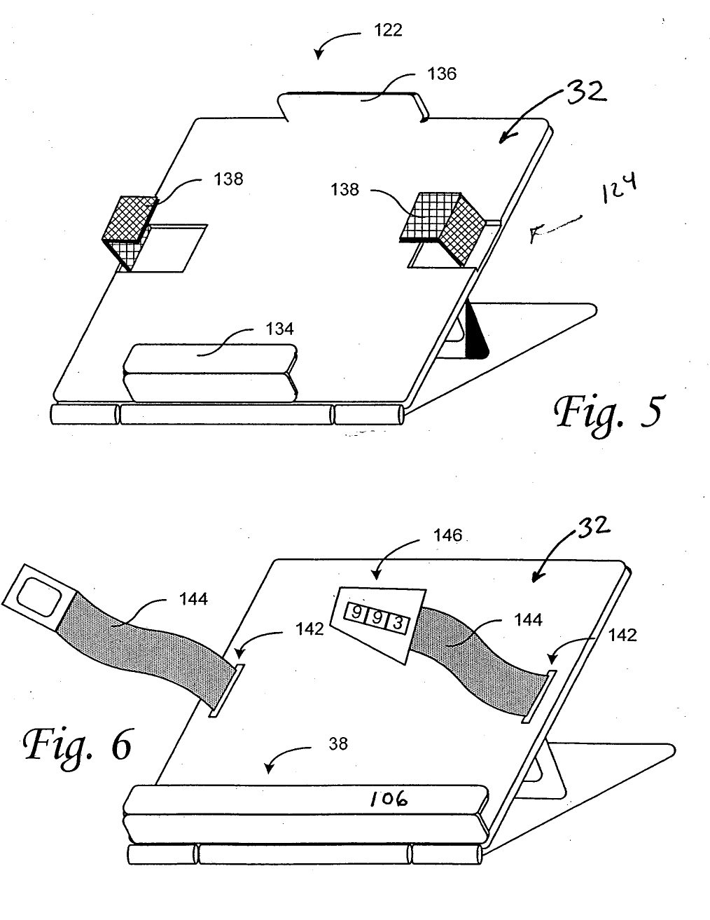

FIG. 6 is a diagram illustrating yet another embodiment for securing a computing device to the computer stand in accordance with one embodiment of the invention. Referring now to FIG. 6, two apertures 142 or other openings can be provided on platform 32. In the illustrated example, apertures 142 are provided along the periphery of platform 32 on opposite sides. A nylon strap 144 or other like flexible member can be threaded through the apertures 142 and around the computing device. As such, apertures 142 are preferably sized to accommodate strap 144. Nylon strap 144 can include a latch or clasp as well as a locking mechanism 146 to allow the strap 144 to be locked in place securing the computing device to platform 32. Preferably, in this embodiment, retaining member 38 is configured as a channel 102, angle bracket 106, or other like structure to provide additional holding security to the computing device.

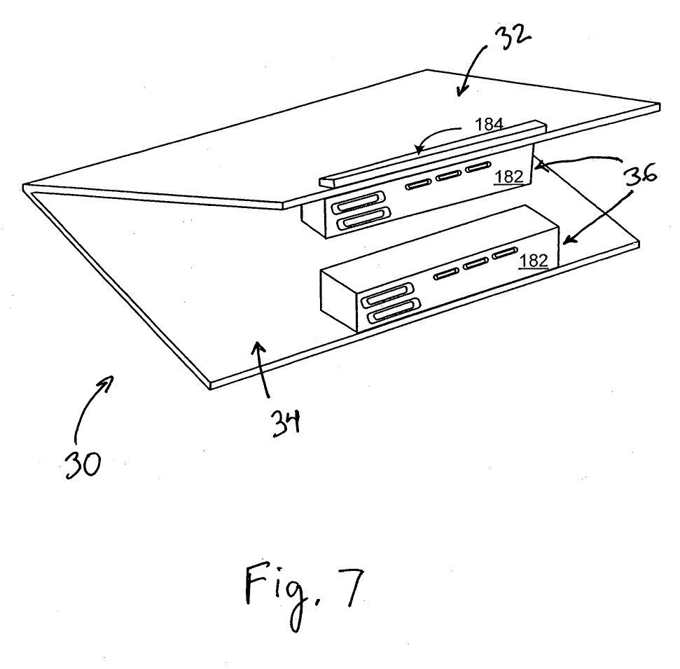

FIG. 7 is a diagram illustrating a rear perspective view of a computer stand 30 in accordance with one embodiment of the invention. Referring now to FIG. 7, the computer stand 30 can include an interface mechanism 182 to provide a docking, interconnect or other like functions to the computing device. In some embodiments, the interface mechanism may be a port replicator, a USB hub, a power outlet, or other device that enhances the utility of the computer stand or the connectivity of the electronic device.

In the example depicted in FIG. 7, two locations for an interface mechanism 182, in this case a port replicator, are depicted to illustrate a couple of possibilities. These example locations are on the bottom surface of platform 32, or on base structure 34. In these two locations, the port replicator can serve in part as the support mechanism or structure 36. Alternatively, a separate support structure 36 may be included. The interface mechanism 182 can be placed anywhere convenient on the computer stand 30. An appropriate connecter or connecters can be provided to interface the computing device to the interface mechanism such as, for example, connecters found on conventional docking stations and port replicators. As such, the computer stand 30 can function as a docking station or port replicator in this embodiment of the invention. In embodiments utilizing a connecter 184 and interface mechanism 182, cables and other interconnects can be provided internal to the structure of the computer stand 30 to provide tangle-free operation and a neat appearance. Where an integrated connecter 184 is not provided, or where wire or cable routing is a concern, an appropriate channel or other light structure (not illustrated) can be included to organize and help retain cable lines that may be connected between the computing device and the interface mechanism 182.

The computer stand 30 can also include an AC, DC, or combined AC/DC power converter to provide the appropriate power conditioning to power the computing device. The power adapter and port replicator can be integrated an integral part of the computer stand 30. In alternative embodiments, slots, compartments, or other accommodations can be made for the addition of a modular port replicator or power adapter.

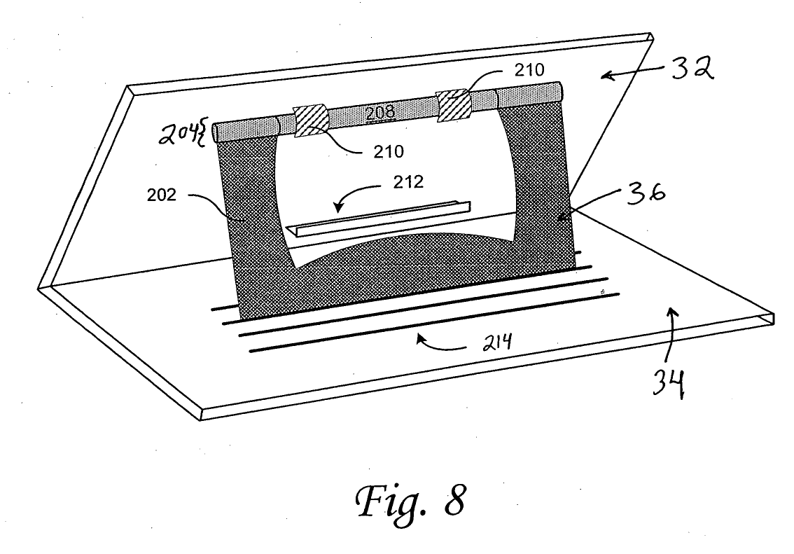

As stated above with reference to FIG. 1, a support mechanism or structure 36 of various configurations can be provided to support platform 32 in an elevated position with reference to a work surface. As seen in FIG. 7, support structure 36 can be configured to serve as an interface mechanism 182-for example, a port replicator or USB hub. FIG. 8 is a diagram illustrating another exemplary configuration of a support structure 36 in accordance with one embodiment of the invention. Referring now to FIG. 8, support structure 36 in the illustrated example includes a generally U-shaped bracket 202 that is pivotally mounted to the underside of platform 32. In operation, U-shaped bracket 202 can pivot at various angles with respect to platform 32 such that the angular elevation of platform 32 can be adjusted accordingly. Any of a number of different pivot mechanisms 204 can be included to provide the pivotal motion. As illustrated in FIG. 8, this example includes a spindle-like structure 208 interconnected between opposite ends of U-shaped bracket 202. Curved bushings 210 engage spindle 208 such that it can be fixedly secured to platform 32 yet be free to rotate about its axis.

Additionally, in the illustrated example, latches 212 are provided to secure bracket 202 in a “closed” position when the computer stand 30 is folded. In one embodiment, latches 212 can be simply snap-fit latches such that bracket 202 can be snapped into a closed position when not in use. Also illustrated in FIG. 8 are a plurality of locking members 214 that can provide secure stops to hold bracket 202 in place in a plurality of open positions. As this example serves to illustrate, any of a number of different pivot mechanisms can be implemented to provide a movable support structure 36 to allow the computer stand 30 to be opened and closed as well as maintained in a given position. Additionally, although the bracket 202 is illustrated as being pivotally mounted to the bottom surface of platform 32, it could also be mounted to the top surface of base structure 34.

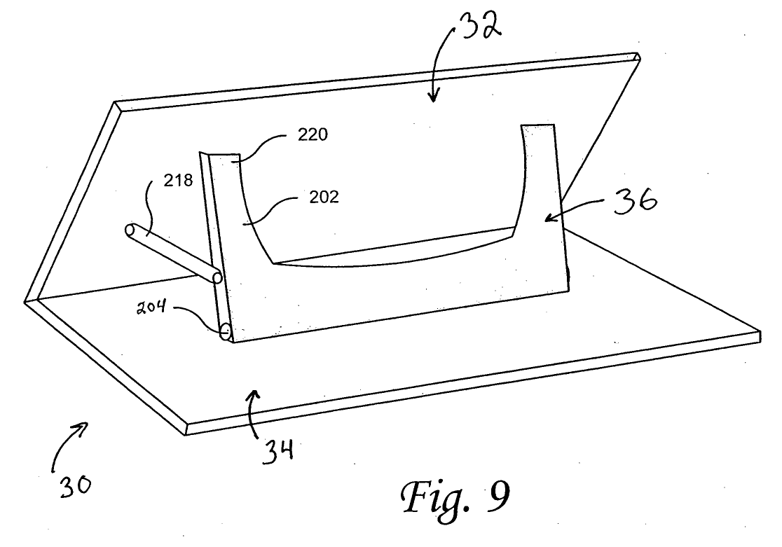

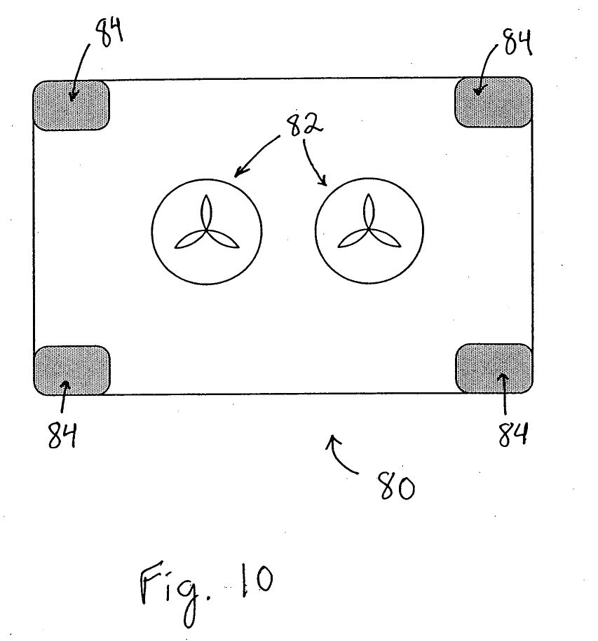

FIG. 9 is a diagram illustrating yet another example configuration for a support structure 36 in accordance with one embodiment of the invention. Referring now to FIG. 9, in this example, a support bracket 202 is pivotally mounted to base structure 34 by a pivot mechanism 204. Bracket 202 is also mounted to platform 32 by way of a pair of pivoting arms 218. Distal ends of bracket 202 can engage the lower surface of platform 32 to provide appropriate support for platform 32 in an open position. The configuration of pivot mechanism 204 and pivot arms 218 allow bracket 202 to be articulated to provide a variety of height configurations for platform 32 as well as to fold into a closed position to allow the computer stand 30 to be closed to a relatively flat configuration.

In various embodiments of the invention, one or more storage compartments can be provided, for example, in base structure 34 or platform 32, to allow the storage of computer related accessories or other devices. Thus, in these embodiments, platform 32 or base structure 34 can be implemented so as to have a certain depth associated therewith to accommodate the storage of such devices. Thus, for example, in one embodiment, the computer stand 30 can take on a cigar box-like structure to provide storage of peripherals and accessories or to provide locations in which to place port replicators, AC adaptors, or other like devices.

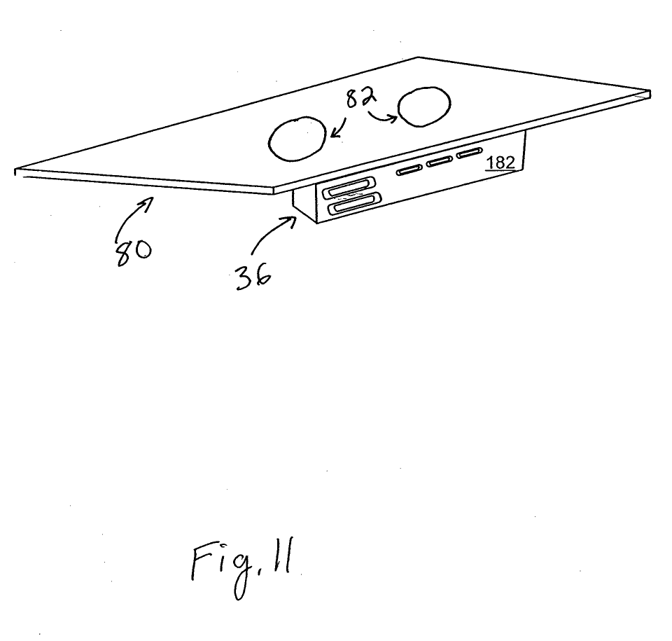

As described above, active cooling devices 80 of various configurations can be provided with the computer stand 30 as either integrated or modular add-on components. A few example embodiments of such active devices are now described. FIG. 10 is a diagram illustrating an example active cooling device 80 in accordance with one embodiment of the invention. Referring now to FIG. 10, this example active cooling device includes two cooling fans 82 to provide a flow of air around the base of the computing device mounted on the computer stand 30. Although two cooling fans 82 are illustrated, any number of cooling fans can be included depending on the airflow capacity of the chosen fans and the cooling requirements of the computing device.

Also illustrated in the example embodiment of FIG. 10 are a plurality of risers 84 that can be used to provide separation of the computing device from the active cooling device. This can allow for additional airflow circulation along the bottom of the computing device. In the embodiment illustrated in FIG. 10, four such risers 84 are depicted as being disposed on each of the corners of the active cooling device. This configuration is provided by way of example only and other such risers 84 in various shapes, configurations and depths can be provided to separate the base of the computing device from the active cooling device to provide a desired volume of air flow.

Additionally, a grating, screen, lattice or other framework (not illustrated) used to prevent large objects (such as, for example, fingers) from coming into contact with the fan blades can be configured such that they are elevated from the planar surface of the active cooling device. In this manner, these structures themselves can provide separation between the computing device and the active cooling device allowing a desired amount of airflow circulation. Rubber or rubber-like surfaces, or other materials with a relatively high coefficient of friction can be added to the surface of the active cooling device or risers 84 to provide a relatively non-stick surface to accept the computing device.

As also stated above, in one embodiment, the active cooling device 80 can be configured in such a way as to be a modular add-on to the computer stand 30. Thus, mounting ridges can be provided on the cooling device or in the stand to allow such modular integration. In some embodiments, a modular active cooling device may be configured to fit into an opening in the platform, supported by a support member and secured by a catch mechanism. In some embodiments, the active cooling device can be dual purpose, configured to be used as a modular component of computer stand 30 as well as used as a standalone device separate from the computer stand 30. Additionally, as stated above, active cooling mechanisms other than a cooling fan 82 can be used to provide the desired cooling effect. For example, Peltier devices can be used to provide a cool surface on which to place the computing device. Such active cooling devices typically require a source of power for operation. As such, in standalone embodiments, an appropriate power source (batteries, solar power, AC power, and so on) can be provided with the active cooling device such that it can operate in a standalone fashion. In embodiments where the active cooling device is integrated with a computer stand 30, power to the cooling device can be provided by way of the computer stand 30.

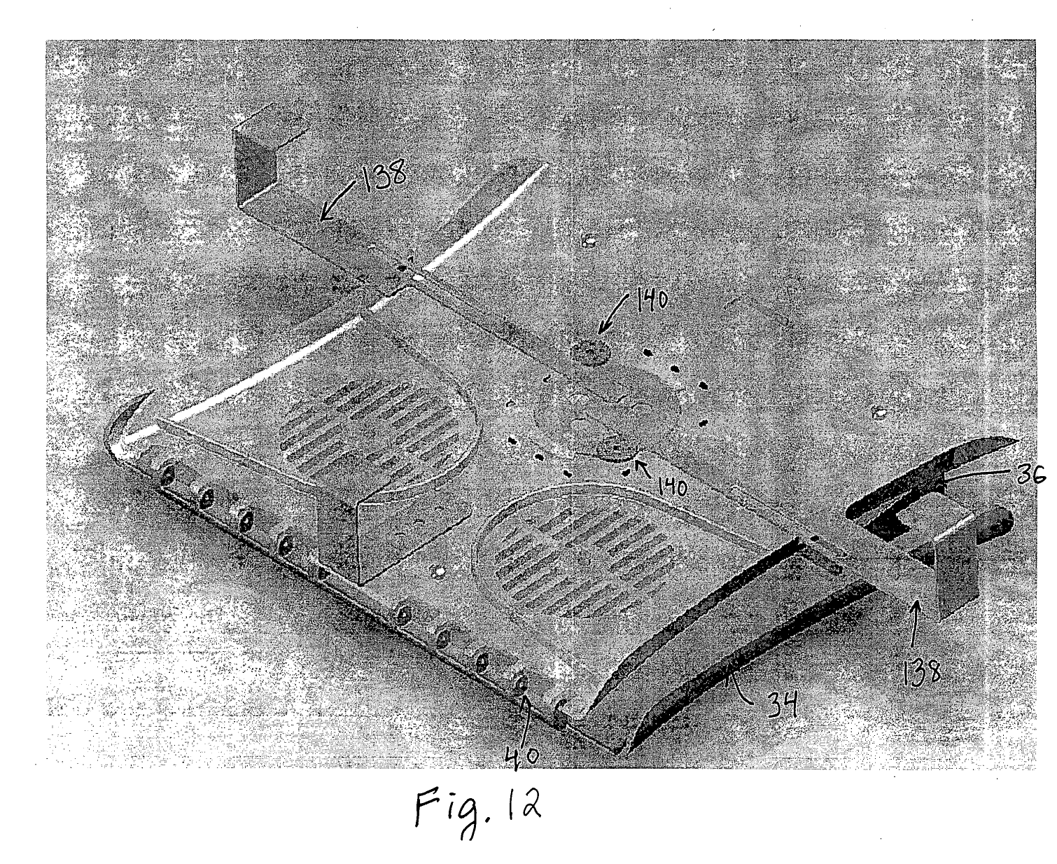

As somewhat of a hybrid embodiment, the active cooling device can be provided with an interface mechanism 182, such as a port replicator, to provide a relatively simple computer stand 30. FIG. 11 is a diagram illustrating an example implementation for an active cooling device implemented as a computer stand 30 in accordance with one embodiment of the invention. Referring now to FIG. 11, the active cooling device 80 is disposed in angular relation to a support mechanism 36. Support mechanism 36 can be pivotedly or fixedly mounted to the undersurface of active cooling device 80 such as to allow active cooling device 80 to be elevated from the work surface. In one embodiment, an interface mechanism 182—for example, a port replicator, power outlet, or USB hub-can be included to provide connectivity for this embodiment of the computer stand 30. In one embodiment, an interface mechanism 182 may serve as the support mechanism 36 to elevate the active cooling device 80 from the work surface. As with other embodiments, a retaining member 38 (not illustrated in FIG. 11) can also be included as can the other features and functionality associated with the computer stand 30.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but can be implemented using a variety of alternative architectures and configurations. Additionally, although the invention is described above in terms of various exemplary embodiments and implementations, it should be understood that the various features and functionality described in one or more of the individual embodiments are not limited in their applicability to the particular embodiment with which they are described, but instead can be applied, alone or in some combination, to one or more of the other embodiments of the invention, whether or not such embodiments are described and whether or not such features are presented as being a part of a described embodiment. Thus the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed across multiple locations.

What is claimed is:

1. A computer stand, comprising:
a platform having a substantially planar portion that comprises a first surface, the planar portion defining a first and second axis, wherein the platform is further configured to support a computing device;
a support mechanism attached to the platform, wherein the support mechanism is configured to elevate at least one end of the platform above a work surface; and
a cooling mechanism disposed on the platform, wherein the cooling mechanism is configured to facilitate heat dissipation from a computing device.

2. The computer stand of claim 1, wherein the cooling mechanism comprises a passive or active cooling mechanism.

3. The computer stand of claim 2, wherein the passive cooling mechanism comprises at least one of perforations, slots, porous materials, meshed materials, other permeable materials, and other openings.

4. The computer stand of claim 2, wherein the active cooling mechanism is an integral part of the platform.

5. The computer stand of claim 4, wherein the active cooling mechanism comprises a cooling fan or Peltier device.

6. The computer stand of claim 2, wherein the active cooling mechanism is a modular component that is removably mounted in or on the platform.

7. The computer stand of claim 6, wherein the active cooling mechanism comprises a cooling fan or Peltier device.

8. The computer stand of claim 6, wherein the modular component is removably mounted in an opening configured to passively cool a computing device when the modular component is not mounted in the opening, and wherein the opening comprises a support member at least partially extending around the opening to hold the modular component and a catch mechanism to secure the modular component when mounted in the opening.

9. The computer stand of claim 6, wherein the modular component may be used as a stand-alone device to cool a computing device when the modular component is not mounted in the platform.

10. The computer stand of claim 1, wherein the support mechanism comprises an interface mechanism.

11. The computer stand of claim 1, wherein the platform comprises an interface mechanism.

12. The computer stand of claim 6, wherein the modular component comprises an interface mechanism.

13. The computer stand of claim 1, wherein the computer stand further comprises a locking mechanism, wherein the locking mechanism is integrated with the platform and configured to lock the computing device in place on the platform.

14. The computer stand of claim 1, wherein the platform further comprises embossments, reliefs, or other designs and patterns.

15. The computer stand of claim 1, wherein the support mechanism is further configured to be releasable or adjustable in order to elevate the platform at various heights and angles above the work surface.

16. A computer stand, comprising:
a platform having a substantially planar portion that comprises a first surface, the planar portion defining a first and second axis;
a support mechanism attached to the platform; and
a cooling mechanism disposed on the platform.

17. A computer stand, comprising:
a means for supporting a computing device;
a means for elevating above a work surface at least one end of the means for supporting a computing device; and
a means for cooling a computing device by facilitating heat dissipation.
